(19) United States
(12) Patent Application Publication
(10) Pub. No.: US 2025/0237683 A1
(43) Pub. Date: Jul. 24, 2025

(54) SYSTEMS, DEVICES AND METHODS FOR POWER ESTIMATION

(71) Applicant: Infineon Technologies AG, Neubiberg (DE)

(72) Inventors: Surya Kiran Venkata Rama Musunuri, Bangalore (IN); Eswar Goda, Bangalore (IN)

(21) Appl. No.: 19/017,862

(22) Filed: Jan. 13, 2025

(30) Foreign Application Priority Data
Jan. 18, 2024 (DE) 10 2024 101 476.8

(51) Int. Cl. G01R 21/133

(52) U.S. Cl. CPC G01R 21/133

(57) ABSTRACT

A hardware power estimator (HPE) configured to provide a power estimate for an electronic device includes a scaling circuit configured to receive an input and to generate a scaled non-linear output of the input includes the scaling circuit applying an approximation of an activation function to the input. The HPE further includes a multiply-add (MADD) circuit arrangement configured to generate an output indicating a mathematical power estimation of the electronic device using the output of the scaling. Input to the scaling circuit includes data values representing state information or activity information of one or more components or Intellectual Property (IP) blocks of the electronic device.

### REFERENCE TO RELATED APPLICATIONS

This application claims priority to German Patent Application 102024101476.8, filed on Jan. 18, 2024, the contents of which are hereby incorporated by reference in their entirety.

### TECHNICAL FIELD

Various embodiments generally relate to power estimation of electronic devices.

### BACKGROUND

Managing power consumption in embedded devices is crucial for prolonging battery life and minimizing the environmental footprint of a system. With the growing emphasis on this aspect in system design, estimating power usage at the system level has become increasingly challenging. This complexity applies to a wide range of scenarios, from IoT applications with numerous embedded devices to automotive applications like engine control modules and powertrain modules, as well as industrial setups equipped with sensors. For example, automotive microcontrollers incorporate accelerators that exhibit significant variations in dynamic power consumption based on their configuration and data pipeline.

There has been a paradigm shift towards power aware methodologies to integrate a System-on-Chip (SoC). Power aware designs and technologies with inputs based on accurate pre-silicon power consumption are extensively used in modern SOCs. These techniques have to utilized at silicon/hardware level as well to manage system power more efficiently. Estimating the dynamic power consumption in run time allows faster and better power management schemes (such as DVC, DVFS, etc.) to be utilized in a given system. Further, estimating the power for complete system, that is summation of all individual SoCs/ASICs, with real time OS/software running on complex hardware, leads to global optimization of power/energy consumption.

Currently, estimating the average power consumption of microcontrollers and ASICs for specific use cases requires gate-level, RTL simulations or timing-based activity simulations. Simulation time constraints and complexity of converting user codes into vectors prevent quick estimation of average power consumption for iterative power-performance optimization of complex application use cases. Moreover, due to implementation constraints, it is impractical to use the same techniques to realize hardware-based power estimators. Hence, modern SoCs use power management IP that aggregates various IP logic states to arrive at overall system power states (Deep sleep, sleep, idle, standby, etc.). These states are then used by the power management controller to optimize the overall power.

In general, microcontrollers include several processing units, different types of memory cells and multiple instances of peripherals. Each of the IPs in turn support different configurations. For example, CPU cores can be run at different frequencies, with and without lockstep between cores, and at different activity factors (IPC rates). IO interfaces, such as CAN, support different baud rates, various power management states, etc. So, theoretically, there would be several million combinations of unique configurations for such microcontrollers. Moreover, a typical application dynamically switches the microcontrollers between some of these configurations. For example, accelerators used in ADAS or visual computing systems support several configurations with variable data and bus load sizes. This further increases the complexity of estimating or modelling the dynamic power behavior of such systems. In specific cases such as microcontrollers, digital logic power consumption is dependent on its configuration as compared to general purpose microprocessors where size and complexity of software can influence power consumption. Currently, estimating average dynamic current consumption of such microcontroller user software requires either current measurement on silicon or gate level silicon simulation (in pre-silicon phase).

### BRIEF DESCRIPTION OF THE DRAWINGS

In the drawings, like reference characters generally refer to the same parts throughout the different views. The drawings are not necessarily to scale; emphasis instead generally being placed upon illustrating the principles of the invention. In the following description, various embodiments of the invention are described with reference to the following drawings, in which:

FIG. 1A is a diagram illustrating a microcontroller unit according to at least one exemplary embodiment of the present disclosure.

FIG. 1B is a table showing configurations for a microcontroller unit.

FIG. 2 is a block diagram of a hardware power estimator according to one or more aspects of the present disclosure.

FIG. 3 shows an example of a scaling circuit according to one or more aspects of the present disclosure.

FIG. 4 shows plots of activation functions according to one or more aspects of the present disclosure.

FIGS. 5-7 show examples of a multiply-add (MADD) or multiply-accumulate (MAC) circuits in accordance with aspects of the present disclosure.

FIG. 8 shows a hardware power estimator network according to one or more aspects of the present disclosure.

FIGS. 9 and 10 each show an exemplary flow diagram and environment for determining the weights or weighted set of values for HPEs in accordance with aspects of the present disclosure.

FIGS. 11 and 12 show methods according to aspects of the present disclosure.

### DESCRIPTION

The following detailed description refers to the accompanying drawings that show, by way of illustration, specific details and embodiments in which the invention may be practiced.

The word “exemplary” is used herein to mean “serving as an example, instance, or illustration.” Any embodiment or design described herein as “exemplary” is not necessarily to be construed as preferred or advantageous over other embodiments or designs.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e., one or more. Any term expressed in the plural form that does not expressly state “plurality” or “multiple” likewise refers to a quantity equal to or greater than one. The terms “proper subset”, “reduced subset”, and “lesser subset” refer to a subset of a set that is not equal to the set, i.e., a subset of a set that contains fewer elements than the set.

The terms “at least one” and “one or more” may be understood to include a numerical quantity greater than or equal to one (e.g., one, two, three, four, [ . . . ], etc.).

As used herein, unless otherwise specified, the use of the ordinal adjectives “first”, “second”, “third”, etc., to describe a common object merely indicate that different instances of like objects are being referred to, and are not intended to imply that the objects so described must be in a given sequence, either temporally, spatially, in ranking, or in any other manner.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in the form of a pointer. However, the term data is not limited to the aforementioned examples and may take various forms and represent any information as understood in the art.

The term “processor” or “controller” as, for example, used herein may be understood as any kind of entity that allows handling data, signals, etc. The data, signals, etc., may be handled according to one or more specific functions executed by the processor or controller.

A processor or a controller may thus be or include an analog circuit, digital circuit, mixed-signal circuit, logic circuit, processor, microprocessor, Central Processing Unit (CPU), Neuromorphic Computer Unit (NCU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

A “circuit” as used herein is understood as any kind of logic-implementing entity, which may include special-purpose hardware or a processor executing software. A circuit may thus be an analog circuit, digital circuit, mixed-signal circuit, logic circuit, processor, microprocessor, signal processor, Central Processing Unit (“CPU”), Graphics Processing Unit (“GPU”), Neuromorphic Computer Unit (NCU), Digital Signal Processor (“DSP”), Field Programmable Gate Array (“FPGA”), integrated circuit, Application Specific Integrated Circuit (“ASIC”), etc., or any combination thereof. Any other kind of implementation of the respective functions, which will be described below in further detail, may also be understood as a “circuit.” It is understood that any two (or more) of the circuits detailed herein may be realized as a single circuit with substantially equivalent functionality. Conversely, any single circuit detailed herein may be realized as two (or more) separate circuits with substantially equivalent functionality. Additionally, references to a “circuit” may refer to two or more circuits that collectively form a single circuit.

As utilized herein, terms “module”, “component,” “system,” “circuit,” “element,” “interface,” “slice,” “circuitry,” and the like are intended to refer to a set of one or more electronic components, a computer-related entity, hardware, software (e.g., in execution), and/or firmware. For example, circuitry or a similar term can be a processor, a process running on a processor, a controller, an object, an executable program, a storage device, and/or a computer with a processing device. By way of illustration, an application running on a server and the server can also be circuitry. One or more circuits can reside within the same circuitry, and circuitry can be localized on one computer and/or distributed between two or more computers. A set of elements or a set of other circuits can be described herein, in which the term “set” can be interpreted as “one or more.”

As used herein, a “signal” may be transmitted or conducted through a signal chain in which the signal is processed to change characteristics such as phase, amplitude, frequency, and so on. The signal may be referred to as the same signal even as such characteristics are adapted. In general, so long as a signal continues to encode the same information, the signal may be considered as the same signal.

As used herein, a signal that is “indicative of” a value or other information may be a digital or analog signal that encodes or otherwise communicates the value or other information in a manner that can be decoded by and/or cause a responsive action in a component receiving the signal. The signal may be stored or buffered in a computer-readable storage medium prior to its receipt by the receiving component. The receiving component may retrieve the signal from the storage medium. Further, a “value” that is “indicative of” some quantity, state, or parameter may be physically embodied as a digital signal, an analog signal, or stored bits that encode or otherwise communicate the value.

It will be understood that when an element is referred to as being “connected” or “coupled” to another element, it can be physically connected or coupled to the other element such that current and/or electromagnetic radiation (e.g., a signal) can flow along a conductive path formed by the elements. Intervening conductive, inductive, or capacitive elements may be present between the element and the other element when the elements are described as being coupled or connected to one another. Further, when coupled or connected to one another, one element may be capable of inducing a voltage or current flow or propagation of an electromagnetic wave in the other element without physical contact or intervening components. Further, when a voltage, current, or signal is referred to as being “applied” to an element, the voltage, current, or signal may be conducted to the element by way of a physical connection or by way of capacitive, electromagnetic, or inductive coupling that does not involve a physical connection.

As used herein, “memory” is understood as a non-transitory computer-readable medium where data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, etc., or any combination thereof. Furthermore, registers, shift registers, processor registers, data buffers, etc., are also embraced herein by the term memory. A single component referred to as “memory” or “a memory” may be composed of more than one different type of memory and thus may refer to a collective component comprising one or more types of memory. Any single memory component may be separated into multiple collectively equivalent memory components and vice versa. Furthermore, while memory may be depicted as separate from one or more other components (such as in the drawings), memory may also be integrated with other components, such as on a common integrated chip or a controller with an embedded memory.

The term “software” refers to any type of executable instruction, including firmware.

Unless specifically stated otherwise, discussions herein using words such as “processing,” “computing,” “calculating,” “determining,” “presenting,” “displaying,” or the like may refer to actions or processes of a machine (e.g., a computer/processor/etc.) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

Exemplary embodiments of the present disclosure may be realized by one or more computers (or computing devices) reading out and executing computer-executable instructions recorded on a storage medium (e.g., non-transitory computer-readable storage medium) to perform the functions of one or more of the herein-described embodiment(s) of the disclosure. The computer(s) may comprise one or more of a central processing unit (CPU), a microprocessing unit (MPU), or other circuitry, and may include a network of separate computers or separate computer processors. The computer-executable instructions may be provided to the computer, for example, from a network or a non-volatile computer-readable storage medium. The storage medium may include, for example, one or more of a hard disk, a random-access memory (RAM), a read-only memory (ROM), a storage of distributed computing systems, an optical drive (such as a compact disc (CD), digital versatile disc (DVD), or Blu-ray Disc (BD), a flash memory device, a memory card, and the like. By way of illustration, specific details and embodiments in which the invention may be practiced.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

It is to be understood that other embodiments may be utilized and structural or logical changes may be made without departing from the scope of the present disclosure. Therefore, the following detailed description is not to be taken in a limiting sense. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment. The appearances of the phrase “for example,” “in an example,” or “in some examples” are not necessarily all referring to the same example.

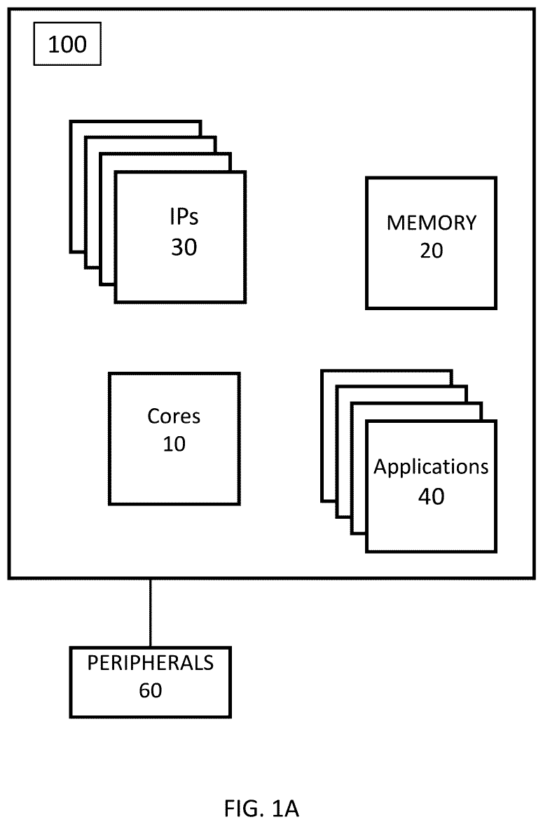

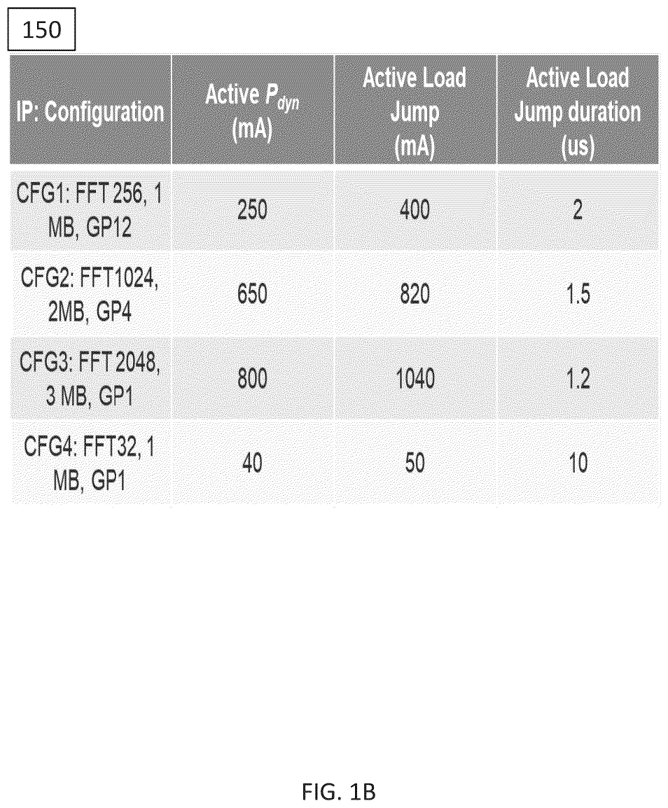

FIG. 1A includes a block diagram of a microcontroller or microcontroller unit (MCU) 100 according to one or more exemplary embodiments of the present disclosure.

The MCU 100 or microcontroller 100 includes one or more cores 10, a memory or memory circuit 20, one or more intellectual property (IP) blocks 30, and one or more other applications 40. Other components may be included but are not shown. Connections are between the components of the microcontroller 100 may be assumed although are not depicted in FIG. 1. The MCU 100 may be implemented as part of SoC.

Referring to FIG. 1A, the one or more cores 10 may be processor or central processing unit (CPU) cores. The one or more cores 10 can perform one or more operations by executing program instructions or software. For example, the applications 40 may be in the form of instructions that are to be performed by the one or more cores. Instructions or software described herein may be stored or located on a (non-transitory) computer readable storage medium located in the microcontroller 100 or SoC, or is otherwise accessible to the cores 10. For example, the MCU 100 can include a memory circuit 20 that may include a computer storage medium for storing instructions to be executed by the cores 10.

An Intellectual Property (IP) block 30 may refer to a reusable element of logic, circuitry, software, or chip layout. An IP block or IP may support multiple functions, in some cases, implemented by one or more devices included in the IP block and/or may be implemented, at least in part, by the one or more processor cores.

In addition, one or more peripheral devices 60 can be operably coupled to the MCU 100.

In general, for electronic devices including digital logic devices, power consumption includes leakage and dynamic components. Leakage power is generally a function of fabrication process parameters (threshold voltage, mobility, etc.) and the voltage. However, the dynamic power is dependent on the switching activity of the logic gates within the integrated circuit logic. Consumption of dynamic power can be written as

$${P}_{dyn} = {V}^{2} {\dot{\sum }}_{i} {f}_{i} {α}_{i} {C}_{i} \qquad Equation ( 1 )$$

Where:
   α denotes the activity of a given node/net of the logic circuit,
   C denotes the effective capacitance
   V denotes voltage,
   and f or feff denotes the effective frequency.

Typically, modern silicon designs use several similar cells, called standard cells, across the entire logic design. For example, many state machines would be realized using certain type of flip-flops, each consisting of standard logic gates of certain threshold voltage. Each of the standard cells, for example, can be abstracted for the calculation of dynamic power. In that case, the total dynamic power can be written as

$${P}_{dyn} = {V}^{2} {\dot{\sum }}_{p} {f}_{eff , p} {N}_{p} {C}_{eff , p} \qquad Equation ( 2 )$$

Where
   N denotes the total cells of a particular type (regular threshold voltage, high threshold voltage, NOR gates, etc.)

The two equations above for calculating dynamic power can be used together for different parts of digital logic. For example, equation (1) can be used to estimate power consumptions of IPs and sub-systems that have high operating frequency, whereas equation (2) can be used for other logic. Accordingly, the total dynamic power can be calculated as:

$${P}_{dyn} = {V}^{2} {\dot{\sum }}_{i} {f}_{i} {α}_{i} {C}_{i} + {V}^{2} \dot{{\sum }_{p}} {f}_{eff , p} {N}_{p} {C}_{eff , p} \qquad Equation ( 3 )$$

Modern microcontrollers, or microprocessors can include several million logic gates. Calculating the dynamic power for these millions of logic nodes/nets increases the computational complexity. Provided a finite set of application use cases (and thereby the chip configuration) is known, a configuration based dynamic power for a given cluster of logic can be correlated with aggregate gate based dynamic power for another set/cluster of logic. Consequently, the total dynamic power can be expressed as

$${P}_{dyn} = {V}^{2} \sum \dot{{p}_{}} [ {f}_{eff , p} {N}_{p} {C}_{eff , p} + \sum \dot{{i}_{}} {f}_{i , p} {α}_{i , p} {C}_{i , p} ] + {V}^{2} \sum \dot{{i}_{}} [ {f}_{i} {α}_{i} {C}_{i} + \sum \dot{{p}_{}} {f}_{eff , p , i} {N}_{p , iCeff , p , i} ] \qquad Equation ( 4 )$$

Using this method recursively would significantly reduce the computational complexity of calculating the dynamic power. These nested equations can then be generically represented as

$${v}_{n} = {\dot{\sum }}_{r} {Y}_{r} {\dot{\sum }}_{q} {X}_{q} , r {\dot{\sum }}_{k} {A}_{k} {W}_{k} , q , r \qquad Equation ( 5 )$$

Equation (5) indicates that the dynamic power calculation can be represented as a series of multiply and addition operations. Accordingly, the dynamic power can be represented as a network of operations, e.g., where every node is a MADD circuit. The inputs Aₖ can be either the activities a or number of cells, Nᵢ. The weight set (W, X, Y) would then effectively represent the remaining terms such as capacitance, voltage in equation (4). Activities of specific nodes and number of logic gates in a pre-defined cell type are fed as inputs.

FIG. 1B shows a table 150 showing various configurations, e.g., for a MCU or SOC. The configurations 1 to 4 (CFG1-CFG4) can be for a particular IP of a MCU/SOC. The configurations CFG1-CFG4 can each be performing a Fast Fourier Transform (FFT) at different resolutions using 1 MB of memory. The table 150 shows the associated power estimation values for each configuration, namely the Active or dynamic power (P_{dyn}), the Active Load Jump current, and the Active Load Jump duration time. In one or more examples of the present disclosure, the power estimation values can be provided by hardware in real-time.

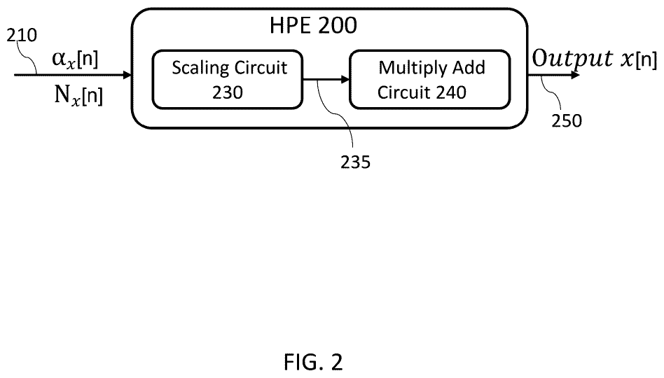

FIG. 2 shows a block diagram of at least one example of a hardware power estimator (HPE) 200 according to one or more aspects of the present disclosure.

The HPE 200 may be implemented in hardware, e.g., with hardware components. Further, the hardware components may also be hardwired. In other words, the HPE 200 may include hardware components or circuits configured to perform one or more functions without a processor and without using software code or executing instructions.

The HPE 200 may be implemented as a part of microcontroller/SoC or be external thereto. The HPE 200 may also be formed as part of a SoC.

The HPE 200 is configured to generate an output 250 indicating an approximation or estimation of power for an electronic device, such a microcontroller or MCU (see e.g., MCU 100 of FIG. 1). In some instances, the output 250 may indicate or specify one or more power consumption related values, e.g., current, voltage, or power (watts).

In another example, the output 250 may function as an indicator pointing to one of several potential power results or a range of potential outcomes, e.g., pointing to an entry in table or list, for example.

Further, in at least one example, the HPE 200 can output a power consumption estimate or power consumption approximation in real-time.

As shown in FIG. 2, the HPE 200 includes a scaling circuit 230 and a multiply-add (MADD) circuit or circuit arrangement 240.

In one or more instances, the scaling circuit 230 can be configured to obtain or receive an input 210 and in response generate a scaled, non-linear output 235 of the input 210. For example, the scaling circuit 230 can apply an activation function, or an approximation of an activation function, to the obtained input. Activation functions are mathematical functions that can introduce non-linearity in various processes. For example, they can transform or map input data in a way so that the input data becomes non-linear in a useful way. Some known activation functions include Sigmoid function, Hyperbolic Tangent (tanh) function, Rectified Linear Unit function (ReLU or Relumax), and Exponential Linear Unit (ELU).

For example, the tanh function maps input values to a range between −1 and 1. The ReLU function outputs the input value directly if the input is positive, and zero if the input is negative, hence introducing non-linearity and sparsity.

The input 210 to the HPE 200 can be a signal (e.g., a digital signal) including data values representing state information or activity information of one or more components or Intellectual Property (IP) blocks of the electronic device. For example, various type of signals of their data can be used as input as they indicate activity or state information about one or more IP blocks or functional components of the MCU 10. For example, the input 210 can include one or more of the following signals, or the data from one or more of the following signals:
an IP enable or disable signal,
an IP configuration register or logic signal (IP activities may be stored or captured as data in configuration (CFG) registers)
a clock configuration register or logic signal,
an IP performance monitoring signal,
a bus utilization equivalent signal,
a hardware Finite State Machine state transition signal, or
a power state signal.

These signals can include data indicating activities or states of the IP blocks, components (functional blocks) of a MCU. That is, these signals can include data or values indicating

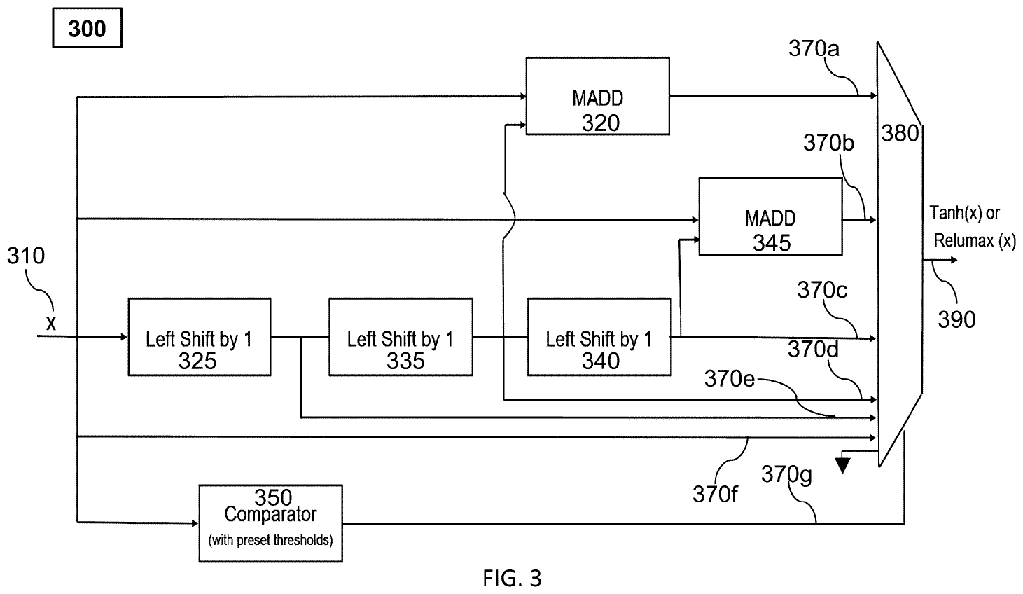

FIG. 3 shows a block diagram of a scaling circuit 300 in accordance with aspects of the present disclosure. The scaling circuit 230 of FIG. 2 can be realized or implemented in a manner resembling the configuration of the scaling circuit 300. As depicted, within circuit 300, there may be various hardware components designed to carry out specific functions. In other words, the scaling circuit 300 can encompass tasks such as performing shift operations, multiplications, addition operations, and summations. Additionally, the scaling circuit 300 incorporates a comparator circuit to handle the task of comparing values.

In at least one example, the components of the scaling circuit 300 may be hardwired and/or may be implemented using with logic devices, without using instructions executed by a processor.

The scaling circuit 300 can perform an approximation of an activation function, such as, tanh activation function or Relu activation function on received input. That is, the scaling circuit 300 can scale or transform received input according to an approximation of an activation function.

The scaling circuit 300 of the example of FIG. 3 can perform the approximation of the activation function on the input 310 in a piecewise manner. For example, from a received input, a plurality of processes or operations can be performed on the input, separately or in parallel, to generate a plurality of outputs. These outputs, (outputs 370a-370g in FIG. 3) generated from the individual piecewise operations or processes are summed together by a summation circuit or multiplexor 380 to generate a total or final output 390 for the scaling circuit 300.

To generate a piecewise output, the scaling circuit 300 can perform any combination of one or more of the following functions or operations, a multiply-add operation, a shift operation, and a comparator operation. Since the input 310 for the scaling circuit can be digital, a binary operation such as shift operations can be performed. Left shifting left a digital value can effective be considered as multiplying by two (2). Similar, a right shift operation or righting be considered as a division by 2. For such operations, it is assumed that the least significant bits reside on the right, while the most significant digits are located on the left.

As depicted in FIG. 3, one piecewise output 370a can be generated or produced by performing a multiply-add operation (using a multiply-adder circuit 320) using the input 310 (first operand) and with using the input 310 after it has been left shifted twice (using left shifter circuits 325 and 335) (second operand).

Similarly, the output 370b can be generated by performing a multiply-add operation (via MADD circuit 345) from the input 310 (first operand) and from the input 310 after it has been left shifted three times (using left shifter circuits 325, 335, and 340) (second operand).

Another piecewise output 370c can be generated simply by left shifting the input 310 three times, using the left shifters 325, 335, and 340. Another piecewise output 370d can be generated by left shifting the input 310 two times using the left shifters 325 and 335. The piecewise output 370e can be generated by right shifting the input 310 once using the left shifter 325.

Further, one piecewise output 370f can be just the input 310 itself, without any operations performed thereon.

In addition, another piecewise output 370g can be generated by using a comparator circuit 350. The comparator circuit 350 compares the input 310 to a predefined value or threshold value to generate the output 370g.

The piecewise outputs 370a-370g can then be summed or multiplexed together by the summation circuit or multiplexor 380 to generate the output 390. Depending on the predefined threshold, the output 390 can approximate a result of an activation function, e.g., a hyperbolic tangent (tanh) or Relu activation function, applied to the input 310.

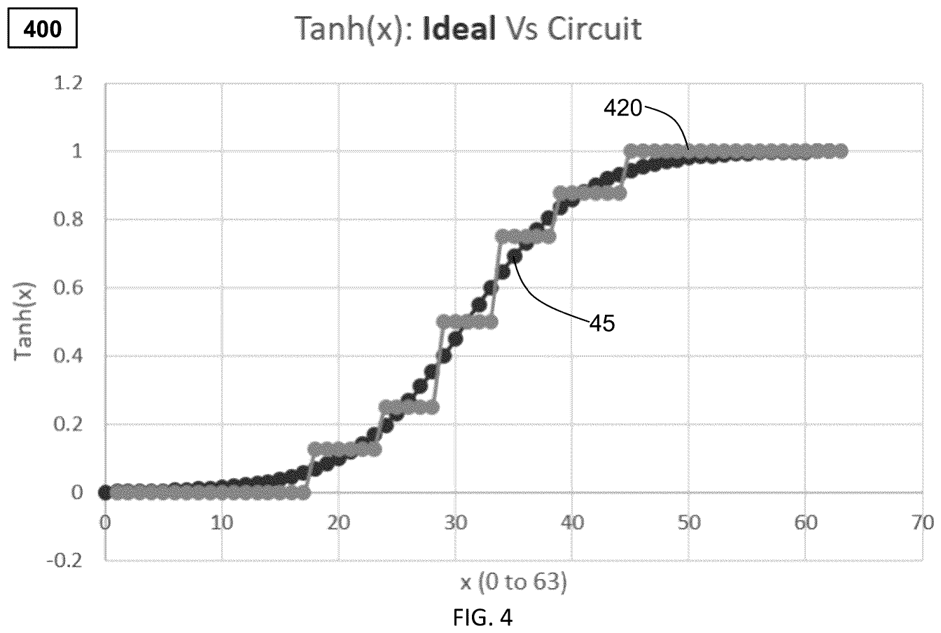

FIG. 4 shows a graphical representation 400 illustrating a plot 410 of an ideal hyperbolic tangent and a plot 420 depicting an approximation of the hyperbolic tangent function, e.g., achieved through a circuit, such as the scaling circuit 300.

The HPE 200 of FIG. 2, after the input 210 has been scaled or transformed by the scaling circuit 230, the MADD circuit 240 operates on this scaled or transformed input. The MADD circuit 240 can include one or more stages.

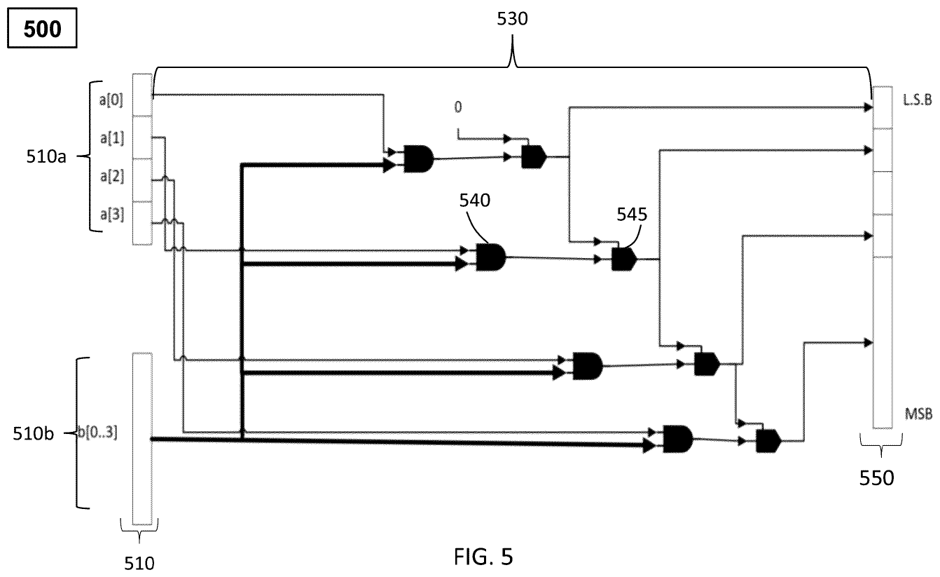

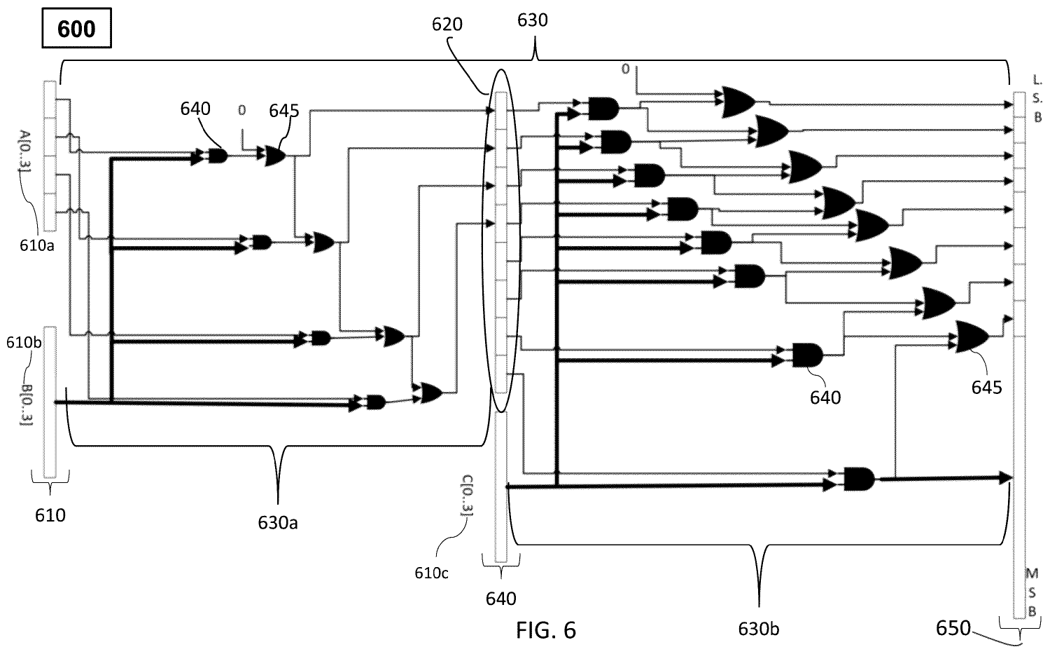

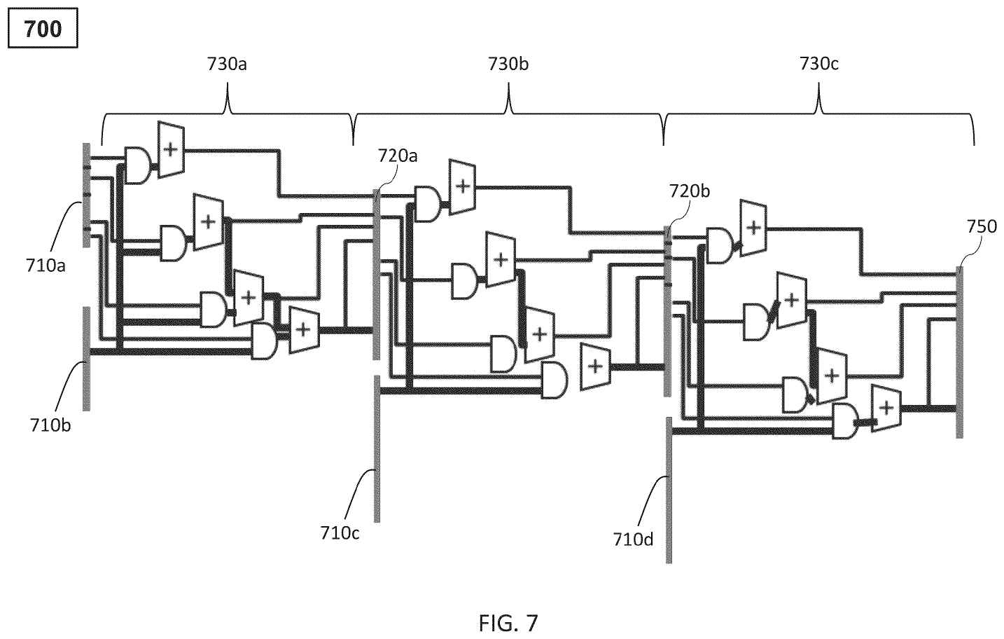

FIG. 5 shows an example of a single-stage multiply-add (MADD) or multiply-accumulate (MAC) circuit 500. FIG. 6 shows an example of a two-stage MADD circuit 600. FIG. 7 shows a three-stage MADD circuit 700. The MADD circuit 240 depicted in FIG. 2, can be realized in a manner closely resembling the configurations of MADD circuits 500-700.

The MADD circuits 500-700 can be configured to perform multiply and add/accumulate operations to output a power consumption estimation. As such, the MADD circuits 500-700 are capable of performing or calculating linear equations to produce an output that reflects an estimation of dynamic power consumption.

In at least one example, the MADD circuits 500-700 may be hardwired and/or may be implemented using with logic devices (e.g., gates), without using instructions executed by a processor.

As mentioned, the single-stage MADD circuit 500 is configured to perform the multiplication and accumulation of two sets of numbers. Said differently, the MADD circuit 500 can be considered a simple 2 input digital circuit for implementing 4-bit multiplication in a single clock cycle.

The MADD circuit 500 includes an input or input layer 510 coupled to an output or output layer 550 via a single stage 530. In the example of FIG. 5, the input or input layer 510 can have or include two (different) inputs or input vectors, namely a [0 . . . 3]) and b [0 . . . 3]. The input vector a or input 510a, can represent scaled input, namely scaled version of data indicating activities and/or the number of active cells or circuits of at least one IP or function block (e.g., of a MCU). This data can be found in signals described herein. The input vector b or input 510b can be weights that when multiplied and added with the input vector a, produce a result indicating a power estimation. The weights of input 510 b can be derived from training and optimization processes.

The weights used for MADD circuits herein may be stored or provided from any suitable storage or non-volatile memory circuit or device operably coupled to the MADD circuit. For example, the HPE 200 of FIG. 2 may be implemented in the MCU 10 of FIG. 1A. The memory circuit 20 may include the weights. In other cases, registers or a of the MCU may include these weights.

The single stage 530 of the MADD circuit 500 includes (four) multipliers 540 and (four) adders 545 that are connected to determine the output 550. The output or output layer 550 can include values indicating real-time dynamic power consumption, e.g., dynamic current of at least one individual component or IP of a MCU or SoC.

FIG. 6 shows another MADD circuit 600 according to at least one exemplary embodiment of the present disclosure. The MADD circuit 600 includes two stages, a first stage 630a and a second stage 630b. In one example, the MADD circuit 240 of the HPE 200 may be implemented similar to the MADD circuit 600. The MADD circuit 600 includes multipliers 640 and adders 645 as shown.

The MADD circuit 600 includes an input or input layer 610 and an output or output layer 650. For the first stage 630a, the input layer 610 has two inputs or input vectors, namely a [0 . . . 3]) or input 610a and b [0 . . . 3]) or input 610b.

The input or input vector 610a can be the scaled input as described herein. For instance, the input 610a can be a scaled version of input indicating activities and/or the number of active cells of an aspect of a MCU, e.g., a IP or functional block. The input vector 610b are weights or weighed values. Again these weights or weighted values may be trained or optimized. The first stage 630a produces a first output, output 620.

For the second stage 630b, another input, input vector c or input 610c is provided for the second stage 630b. The input 610 can be another set of weights or weighted values. These weights or weighted value may also be optimized or trained in accordance with aspects of the present disclosure.

The first input 610a and the second input 610b are used for the first stage, 630a. The first output or the output 620 of the first stage 630a and the input 610c can be used as input for the second stage 630b. The output 650 of the second stage 630b, is also the output for the MADD circuit 600. As such, the output 650 can correspond to the dynamic power consumption for at least one component or IP of microcontroller (e.g., MCU 100) or a SoC. The MADD circuit 600 can produce the output 650 in two clock cycles.

In short, the MADD circuit 600 includes two sequential stages to realize 3-input multiplication, which can be produced or achieved in 2 clock cycles. Extending this concept, a multi-stage MADD circuit could further be realized to process 4-input multiplication that can be achieved in 3 clock cycles. This is illustrated in FIG. 7, featuring a circuit denoted as 700. This circuit 700 can be considered as essentially identical to the other MADD circuits 500 and 600, with the only difference being the inclusion of three stages (730a-730c).

Assuming that each stage n is represented by the equation X×kn+Cn, then, in according to at least one example, a 3 stage network or the 3 stage MADD circuit 700 may be represented by the equation:

$$( ( X * k 1 + c 1 ) * k 2 + c 2 ) * k 3 + c 3 = X * k 1 * k 2 * k 3 + C 1 * k 2 * k 3 + C 2 * k 3 + C 3 \qquad Equation ( 6 )$$

where:
   X represents the number of instances of the IP (which has been scaled by scaling circuit),
   kn represents the average current consumed by the IP (predefined values)
   Cn represents the leakage contribution of the IP.

In one or more examples, the values for k1, k2, k3 and are C1, C2, and C3 different values for the same IP.

Input values X are digital values that can represent following signals (after scaling):
Hardware IP enable/disable logic signals (Example: Core_en signal; ip_inst_en signal)
IP configuration registers/logic signals (Example: Lockstep_en signal)
Clock configuration registers/logic signals (Example: PLL, DLL and divider configuration signals)
IP performance monitoring signals (Example: IPC for compute cores, Baud rates equivalents for communication models)
Bus utilization equivalent signals (Example: bus interconnect usage duty ratio rates)
Hardware Finite State Machine's state transition signals (Example: init_to_active signal for an FSM)
Device and or IP power state signals (Example: Sx signal)

This simple 3 stage MADD circuit 700 can perform the sum of 4 input multiplication, 3 input multiplication and 2 input multiplication. The MADD circuit 700 includes the inputs 710a-710d with intermediate outputs 720a and 720b and final output 750.

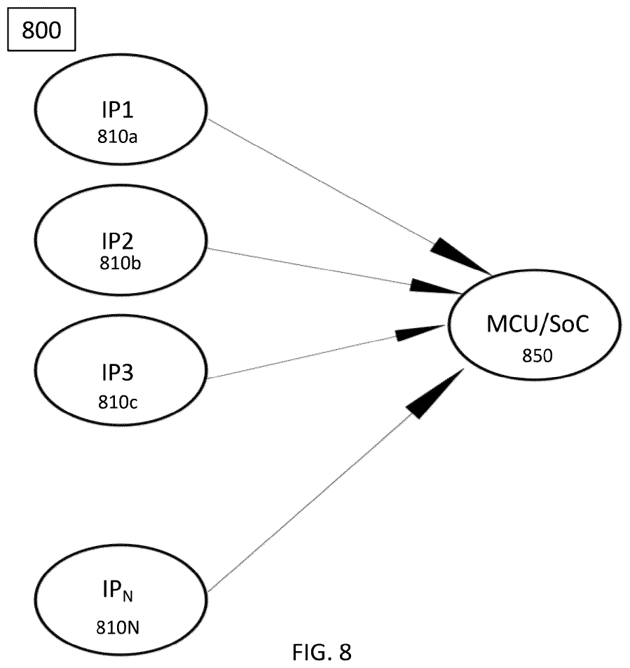

FIG. 8 shows a diagram of a HPE network 800 or aspects thereof. The HPE network 800 can configured to estimate dynamic power consumption, e.g., in real-time, for a MCU or SoC. More specifically, the HPE network 800 can be implemented similar to the HPE 200 of the FIG. 2. Further, the HPE network 800 can provide an instant or real-time estimation of the dynamic power consumption for functional block or IP components of a MCU or SoC 850. The HPE 800 may be implemented in an MCU, including MCUs described herein.

In the HPE network 800, each node 810a-810N can represent at least a HPE or HPE unit which can correspond to a particular IP block. Each node 810a-810N can represent a HPE unit and hence include a scaling circuit and a MADD circuit, e.g., as shown in FIG. 2. The MADD circuits of the HPE units 810a-810N can be implemented as described herein, except that each MADD circuit can be tailored in terms of its weights to a particular corresponding one of the IPs of the MCU/SoC 850.

The HPE network 800 may be realized a hardware (hardwired) network including hardware nodes in the form of HPE units described herein (e.g., HPE 200). The MADD circuits of the nodes 810a-810N may be implemented as in single or multi-stage form; see e.g., MADD circuits 500, 600, or 700.

In some examples, the nodes 810a-810N may only represent MADD circuits because the nodes 810a-810N may share one or more common scaling circuits (e.g., like the scaling circuit 220 of FIG. 2). In such a case, a single scaling circuit may scale inputs, e.g., from the MCU or SoC 850 and provide the scale inputs to each of the nodes 810a-810N. The HPE network 800 may include circuitry for directing the scaled inputs to the appropriate node. The output of each node can represent an estimation of dynamic power consumption (e.g., current, voltage, or power in watts) for the corresponding or associated IP, e.g., of an electronic device (MCU/SoC 850).

In general, as long as the HPE can support the number of gates (multipliers & adders, etc.) required for higher number of MADD stages for all IPs, the current estimation for the entire SoC can be done in the order of few clock cycles. Thus, in effect, the entire HPE network 800 can be implemented to estimate power consumption for a MCU or SoC in within 10 to 16 clock cycles because the power estimation from different MADD circuits for all the IPs or components can done concurrently or in parallel.

Various embodiments herein depict and describe a hardware based power estimators (HPEs) that can estimate the power consumption of the SoC within a few clock cycles, thereby enabling faster dynamic power management.

The various HPEs described herein may be used in both pre and post silicon phase using simple multiply and add circuits that can quickly estimate dynamic power consumption in real-time.

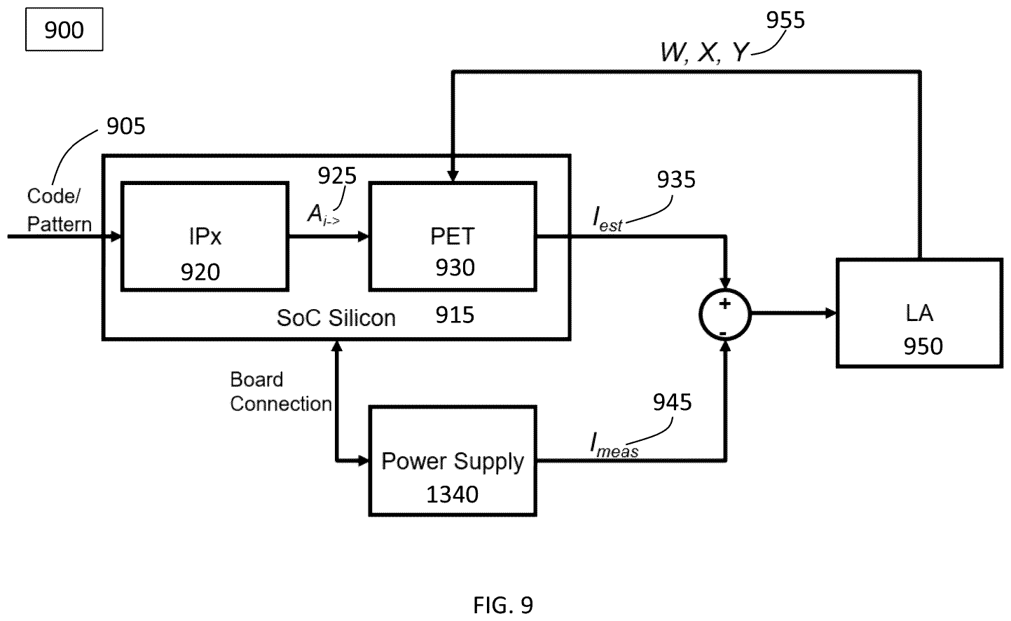

In the post silicon phase, an HPE (implemented as part of silicon) can be used to estimate power consumption of an application/IP Block. Since the HPE can estimate power consumption with very low latency, faster transients/changes in the power consumption can be estimated. This estimated power can be compared against the real power consumption as measured using a power supply (that is supplying to the silicon/DUT). A learning algorithm is used to minimize the least means squared (LMS) loss function and arrive at optimized weights for the HPE, as shown in FIG. 9.

Various embodiments, relate to training a power estimator based on the configuration of each IP, sub-system, SoC or the overall system. Learning algorithms, LMS (least mean squared) multivariate curve fitting (for certain sub-systems or IPs), and neural networks (for other IPs and the complete system-on-chip (SoC)), are used to arrive at coefficients for this estimator (HPE). For example, models for the learning algorithms (LAs) can be trained with current measurements from pre-silicon (using simulators such as PrimePower®) or post-silicon (using power supplies). The models can then be validated with an independent set of application code/software. Further, the HPE implementation can be scaled to accommodate an increase in number of IP instances between derivative products (or different architectures). Moreover, HPE includes both leakage and dynamic components of silicon power consumption, and thus accounts for PVTF variations.

Referring, back to equations (4) and (5), a simple linear equation would work well for each node. Therefore, the following function can be used for training the model for HPE:

$$y = max ( 0 , x ) \qquad Equation ( 7 )$$

For simple linear regression, it can be shown that, the minimum set of training dataset required to arrive at one potential weight set (W, X, Y) is

$${( n + m )}^{5 / 3} + ( n + m ) + {( n + m )}^{1 / 3} . \qquad Equation ( 8 )$$

However, performing training to arrive at a proper or suitable weighted set could be accomplished using a loss function to maximize accuracy. For example, a loss function representing the least mean squared (LMS) error of power estimation of set a leaf cells could be used. As equation (8) is a multivariate non-linear polynomial, typically the training dataset is 5-10 times above the required number and a modified gradient descent algorithm is used for optimizing the weights.

FIG. 9 shows an exemplary flow diagram and environment 900 representing exemplary a post-silicon training process for determining the weights or weighted set of values to be used for HPEs or parts thereof (e.g., MADD circuits) described herein.

For post silicon training, a Power Estimator (PET) or HPE 930 is already implemented as part of silicon or the MCU 915. Thus, the HPE 930 is operable to estimate power consumption of an IP block or application of a MCU, such as any IP, which is denoted IPX 920 in this example.

The MCU or SoC 915 can be provided input, e.g., code or input patterns 905 which causes the at least one IPx 920 to operate or function. The corresponding parameters produced by the IPx 920, e.g., the number of active cells, can be captured and used as input, e.g., as signals described herein, to the HPE 930. Thus, the HPE 930 can produce an output, e.g., an estimated power consumption. This may be in the form of an estimated current Iₑₛₜ, 935 for example. The HPE 930 may have been already configured or set with initial values for the weighted set 945 (Wi, Xj, Yl), which can be stored in registers of the MCU. Again, the HPE 910 can provide an estimate of the power consumption with very low latency. Relatively fast or faster transients or changes in the power consumption can be dynamically estimated.

FIG. 9 shows the estimated power 935 compared against the real power consumption 940, which is measured using a power supply 940. The power supply 940 can be supply power to the device under test (DUT), e.g., the SoC or MCU 910.

The difference between the measured power 945 and the estimated power 935 from the HPE 930 can be used as input by a learning algorithm (LA) 950. The learning algorithm can be implemented as instructions (e.g., stored on non-transitory computer readable medium) and executed by one or more processors, e.g., on a separate computing device. The LA 950 uses current weights 955 and the differences in the power measurements between the directly measured and estimated power consumption to determine optimized weights 955 to be used by the HPE 930. In particular, the LA 950 can be configured to determine an optimized set of weights 955. Any suitable (machine) learning algorithm or techniques can be used to find optimized weights 955. In one example, the LA 950 can use a least means square (LMS) loss function and arrive at optimized weights for the HPE 930.

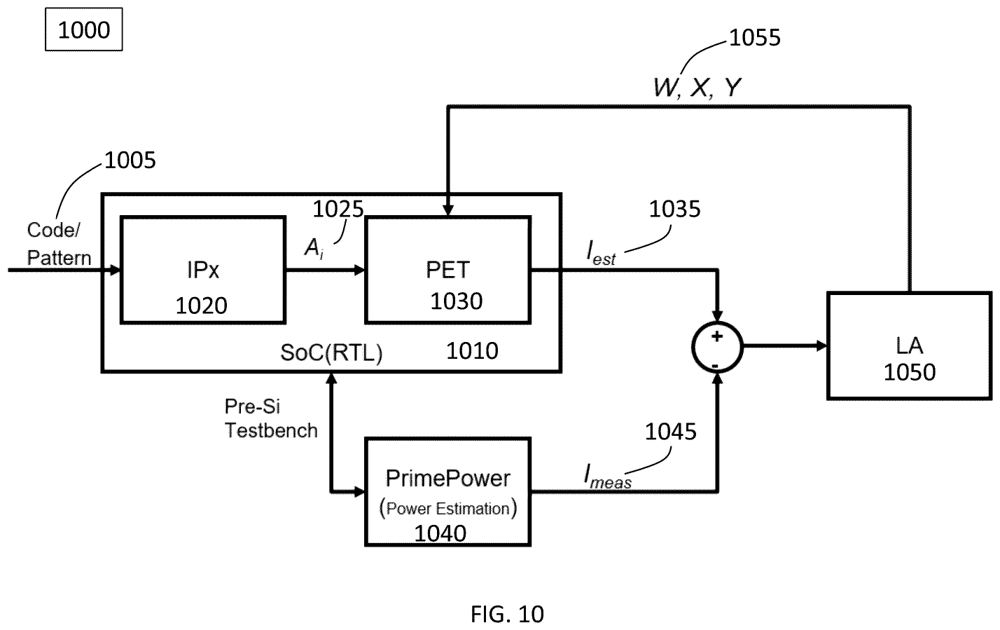

FIG. 10 shows an exemplary flow diagram and an environment 1000 representing an exemplary a pre-silicon training process for determining weights or weighted set of values for HPEs described herein. For a pre-silicon training process, an SoC/MCU 1010 and its components, e.g., IPx 1020, and HPE 1030 is not physically realized and implemented. Instead the SoC/MCU 1010 can be represented as abstract data form for simulation data, e.g., data used for RTL simulation or similar types of simulations.

During simulations different inputs, e.g., codes or patterns, can be input to the simulated SoC/MCU 1010 and thus can cause one or more operations or tasks from the IPx 1010 to be implemented. As in the post-silicon training, the simulated HPE 1010 can produce output of an estimate power consumption. That is, the parameters produced by the IPx 1020, e.g., the number of active cells, can be captured and used as input to the HPE 1030. Again, the power consumption may be in the form of an estimated current Iₑₛₜ, 1035 for example. Similarly, the HPE 1030 may be simulated with initial values for the weighted set 1055 (Wi, Xj, Yl) used for the HPE/PET 1030, which can be updated for later simulation by the weights determined by the LA 1050.

Again, the estimated power consumption 1035 can be compared against the power consumption 1045 produced by simulated power estimator 1040, which can also be a simulated power supply to the SoC/MCU 1010.

As with the post-silicon phase, the difference between the simulated measured power 1040 and the simulated estimated power 1035 from the HPE 1030 can be used by a learning algorithm (LA) 1050 to find optimized weight value.

Again, the LA 1050 can be implemented as instructions (e.g., stored on non-transitory computer readable medium) and executed by one or more processors, e.g., on a separate computing device. As the LA 1050 receives the differences in power measurements, as well as the current set of weights 1045. Using such input, the LA 1050 can be configured to determined optimized weight set 1055. The LA 1050 can use a least means square (LMS) loss function and arrive at optimized weights for the HPE 1030. The LA can be repeatedly or iteratively applied to multiple simulation to update or find the best or optimized set of weights that produce the least error in power consumption produced by the simulated HPE 1030 measuring power consumption. Further, since the HPE is not physically realized, the HPE 1030 can itself be repeatedly optimized or its design or configuration updated accordingly in order to determine a proper result.

It is noted that not all the application codes used in this training set need to be functional (in terms of functionality). During a pre-silicon analysis, a vector driven approach could be used to attain higher coverage of internal nodes. Therefore, a set of patterns (or codes) are used to estimate activity of the logic using simulation or emulation. A Fast Signal Database (FSDB) captures all the node/signal activities and used as an input to industry standard power estimation tools (e.g., PrimePower™ from Synopsys®, Voltus™ from Cadence®, etc.). As discussed later, the power consumption (Iₘₑₐₛ) obtained from these tools can be compared against the estimated power consumption Iₑₛₜ from a realized or implemented HPE. A learning algorithm can be used to minimize the LMS loss function so as to arrive at optimized weights for the HPE.

Without loss of generality, the HPEs described herein, can be thought of as a hardware accelerator for accurate power estimation. Further, HPE can used in both pre- and post-silicon phases to help improve the overall the system power performance in the following ways:
Dynamic Power Management Schemes: In the actual application/use case, the HPE can be used to estimate power is minimal (few clock cycles) latency. This feature of HPE can be utilized by several power management schemes such as Dynamic Voltage Control (DVC), Dynamic Voltage and Frequency Scaling (DVFS), Envelope Tracking, etc.
Predictive Software based Performance Optimization: An application can be designed such that the estimated power using HPE would be available to the processor within a few clock cycles before the actual code implemented. In this case, the core can prepare itself by indicating to the voltage regulator circuit about the need to sink or source more current.
Architecture Exploration: RTL implementations of HPE can be used for architectural comparison analysis. For example, different bus/bridge topologies can be evaluated using a previously trained HPE RTL that model slave IPs.
On-chip and system diagnostics and debug: The real time data from HPE can be used to diagnose issues within an SoC. For example, tracing data from HPE can be used to evaluate previous history of activities within the SoC before an unintended alarm/reset/event. Similarly, HPE trace data from different silicon within a given system can be combined to arrive at an overall state of the system at a given point of time.

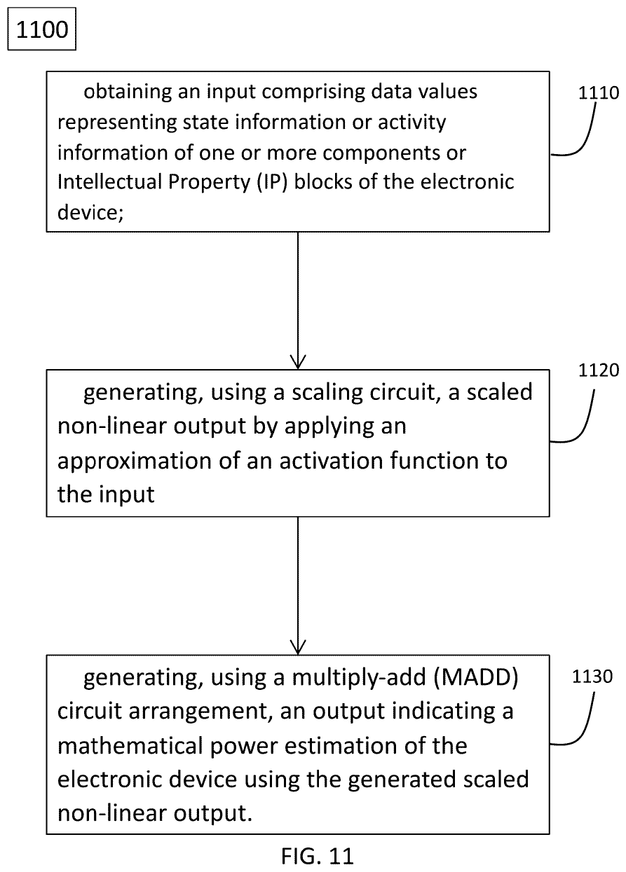

FIG. 11 shows a method 1100 in accordance with aspects of the present disclosure. The method 1100 includes, at 1110, obtaining an input comprising data values representing state information or activity information of one or more components or Intellectual Property (IP) blocks of the electronic device.

At 1120, the method 1100 includes generating, using a scaling circuit, a scaled non-linear output by applying an approximation of an activation function to the input.

At 1130, the method 1100 includes generating, using a multiply-add (MADD) circuit arrangement, an output indicating a mathematical power estimation of the electronic device using the generated scaled non-linear output.

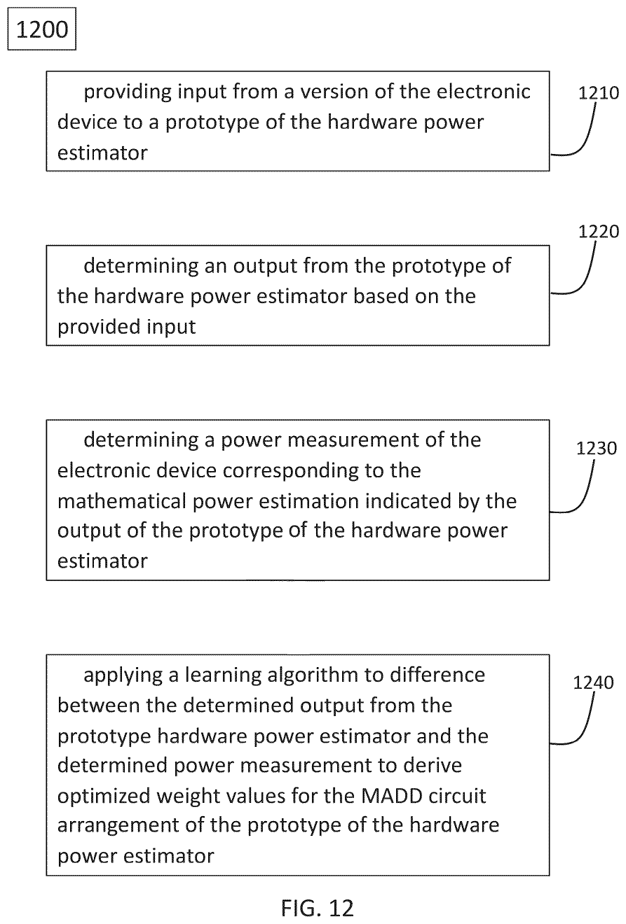

FIG. 12 shows a method 1200 in accordance with aspects of the present disclosure. The method 1200 includes, at 1210, providing input from a version of the electronic device to a prototype of the hardware power estimator.

At 1220, the method 1200 includes determining an output from the prototype of the hardware power estimator based on the provided input.

At 1230, the method 1200 includes determining a power measurement of the electronic device corresponding to the mathematical power estimation indicated by the output of the prototype of the hardware power estimator.

At 1240, the method 1200 includes applying a learning algorithm to difference between the determined output from the prototype hardware power estimator and the determined power measurement to derive optimized weight values for the MADD circuit arrangement of the prototype of the hardware power estimator.

The HPEs described herein can be used along with other software and debug tools to predict power consumption for a given application code, thereby helping optimize application code in an efficient manner. Thus, early information is available for design and architecture teams for planning the silicon parameters.

The following examples pertain to further aspects of this disclosure:

Example 1 is a hardware power estimator (HPE) configured to provide a power estimate for an electronic device, the hardware power estimator including: a scaling circuit configured to receive an input and to generate a scaled non-linear output of the input comprises the scaling circuit applying an approximation of an activation function to the input; and a multiply-add (MADD) circuit arrangement configured to generate an output indicating a mathematical power estimation of the electronic device using the output of the scaling, wherein the input to the scaling circuit comprises data values representing state information or activity information of one or more components or Intellectual Property (IP) blocks of the electronic device.

Example 2 is the subject matter of Example, wherein the scaling circuit may include a plurality of hardware components configured to perform the approximation of the activation function on received input.

Example 3 is the subject matter of Example 2, wherein the scaling circuit may be configured to apply the approximation of the activation function in a piecewise manner to generate, in parallel, a plurality of piecewise outputs, and wherein the scaling circuit may be further configured to sum together the generated piecewise outputs generate the output of scaling circuit.

Example 4 is the subject matter of Example 3, wherein to generate at least one piecewise output, the scaling circuit may be configured to perform a multiply-add operation on the input.

Example 5 is the subject matter of Example 3, wherein to generate at least one piecewise output, the scaling circuit is configured to apply one or more shift operations on the input.

Example 6 is the subject matter of Example 3, wherein to generate at least one piecewise output, the scaling circuit may be configured to apply at least one or more shift operations and at least one multiply-add operation to the input.

Example 7 is the subject matter of Example 3, wherein to generate at least one piecewise output, the scaling circuit may be configured to apply a comparator with predefined thresholds to the input,

Example 8 is the subject matter of any of Examples 1 to 7, wherein the scaling circuit configured to apply an approximation of an activation function may include the scaling circuit to apply an approximation of a hyperbolic tangent function.

Example 9, is the subject matter of any of Example 1 to 8, wherein the scaling circuit configured to apply an approximation of an activation function may include the scaling circuit to apply an approximation of a rectified linear unit function.

Example 10, is the subject matter of any of Examples 1 to 9, wherein the MADD circuit arrangement may include a plurality of MADD circuits arranged in stages so that the output of one stage is input to a subsequent stage.

Example 11 is the subject matter of Example 10, wherein each stage may include a MADD circuit configured to calculate an accumulated sum of product values from between a first input and a second input to the stage, wherein the first input comprises output from a previous stage or output from the scaling circuit, and wherein the second input comprises predefined weight values.

Example 12 is the subject matter of Example 11, wherein the predefined weight values may correspond to one or more electrical parameters and/or states of the electronic device.

Example 13 is the subject matter of Example 11, wherein the predefined weight values may correspond to one or more electrical parameters and/or states of a component of the electronic device.

Example 14 is the subject matter of Example 11, wherein the predefined weight values may correspond to one or more parameters and/or states of a hardware accelerator of the electronic device.

Example 15 is the subject matter of Example 11, wherein the predefined weight values may correspond to one or more parameters and/or states of a IP of the electronic device.

Example 16 is the subject matter of Example 11, wherein the predefined weight values are values that can be determined from a training process.

Example 17 is the subject matter of Example 16, wherein the training process can include a process including: providing simulated input from a simulated hardware electronic device to a prototype of the hardware power estimator, determining a simulated power measurement, and applying a learning algorithm to difference between power estimate from the prototype of the hardware power estimator and simulated power measurement to derive the predefined weight values.

Example 18 is the subject matter of any of Examples 10 to 17, wherein the MADD circuit arrangement may include three stages or less and so as to produce an output from an input in 3 clock cycles or less.

Example 19 is the subject matter of any of Examples 1 to 18, wherein the hardware power estimator may be configured to provide the power estimate for the electronic device in real-time.

Example 20 is the subject matter of any of Examples 1 to 20, wherein the electronic device can be a microcontroller chip.

Example 21 is the subject matter of any of Examples 1 to 20, wherein the MADD circuit arrangement can be configured to generate an output indicating a mathematical power estimation according to the equation

$${P}_{dyn} = {V}^{2} {\dot{\sum }}_{i} {f}_{i} {α}_{i} {C}_{i}$$

where:
α denotes the activity of a given node/net,
C denotes the effective capacitance,
f denotes the effective frequency
V denotes voltage.

Example 22 is the subject matter of any of Examples 1 to 21, wherein the input to the scaling circuit can include an IP enable or disable signal.

Example 23 is the subject matter of any of Examples 1 to 22, wherein the input to the scaling circuit can include an IP configuration register or logic signal.

Example 24 is the subject matter of any of Examples 1 to 23, wherein the input to the scaling circuit can include a clock configuration register or logic signal.

Example 25 is the subject matter of any of Examples 1 to 24, wherein the input to the scaling circuit can include an IP performance monitoring signal.

Example 26 is the subject matter of any of Examples 1 to 25, wherein the input to the scaling circuit can include a bus utilization equivalent signal.

Example 27 is the subject matter of any of Examples 1 to 26, wherein the input to the scaling circuit can include a hardware Finite State Machine state transition signal.

Example 28 is the subject matter of any of Examples 1 to 27, wherein the input to the scaling circuit can include a power state signal.

Example 29 is a microcontroller chip that can include the hardware power estimator of any claims 1 to 29, wherein the electronic device is the microcontroller chip.

Example 30 is the subject matter of Example 20, wherein the microcontroller can include a plurality of functional blocks or IP blocks, wherein at least some of the functional blocks have at least one state variable associated with them; and wherein at least some of the functional blocks are connected to the scaling circuit so that at least some of the state variables function as the said input to the scaling circuit.

Example 1A is a method of hardware power estimation for electronic device, the method including obtaining an input comprising data values representing state information or activity information of one or more components or Intellectual Property (IP) blocks of the electronic device; generating, using a scaling circuit, a scaled non-linear output by applying an approximation of an activation function to the input; and generating, using a multiply-add (MADD) circuit arrangement, an output indicating a mathematical power estimation of the electronic device using the generated scaled non-linear output.

Example 2A is the subject matter of Example 1A, wherein the scaling circuit can include a plurality of hardware components configured to perform the approximation of the activation function on received input.

Example 3A is the subject matter of Example 1A or 2A, wherein applying the activation function to the input can include generating, in parallel, a plurality of piecewise outputs by applying the activation function to the input in a piecewise manner to, and summing together the generated piecewise outputs generate the called non-linear output.

Example 4A is the subject matter of Example 3A, wherein generating at least one piecewise output can include the scaling circuit performing a multiply-add operation on the input.

Example 5A is the subject matter of Example 3A or 4A, wherein generating at least one piecewise output comprises the scaling circuit applying one or more shift operations on the input.

Example 6A is the subject matter of any of Examples 3A to 5A, wherein generating at least one piecewise output may include the scaling circuit applying at least one or more shift operations and at least one multiply-add operation to the input.

Example 7A is the subject matter of any of Examples 3A to 6A, wherein generating at least one piecewise output may include the scaling circuit applying a comparator with predefined thresholds to the input,

Example 8A is the subject matter of any of Examples 1A to 8A, wherein the scaling circuit applying the approximation of an activation function to the input can include the scaling circuit applying an approximation of a hyperbolic tangent function to the input.

Example 9A is the subject matter of any of Examples 1A to 8A, wherein the scaling circuit applying an approximation of the activation function to the input can include the scaling circuit applying an approximation of a rectified linear unit function to the input.

Example 10A is the subject matter of any of Examples 1A to 10A, wherein the MADD circuit arrangement may include a plurality of MADD circuits arranged in stages so that the output of one stage is input to a subsequent stage.

Example 11A is the subject matter of Example 10A, wherein each stage comprises a MADD circuit can be configured to calculate an accumulated sum of product values from between a first input and a second input to the stage, wherein the first input includes output from a previous stage or output from the scaling circuit, and wherein the second input includes predefined weight values.

Example 12A is the subject matter of Example 11A, wherein the predefined weight values can correspond to one or more electrical parameters and/or states of the electronic device.

Example 13A is the subject matter of Example 11A or 12A, wherein the predefined weight values may correspond to one or more electrical parameters and/or states of a component of the electronic device.

Example 14A is the subject matter of any of Examples 11A to 13A, wherein the predefined weight values can correspond to one or more parameters and/or states of a hardware accelerator of the electronic device.

Example 15A is the subject matter of any of Examples 12A to 15A, wherein the predefined weight values may correspond to one or more parameters and/or states of a IP of the electronic device.

Example 16A is the subject matter of any of Examples 11A to 15A, wherein the predefined weight values may be values that can be determined from a training process.

Example 17A, is the subject matter of any of Examples 10A to 16A, wherein the MADD circuit arrangement can include three stages or less, and wherein generating the output using the MADD circuit arrangement comprises generating the output from the scaled non-linear output in 3 clock cycles or less.

Example 18A is the subject matter of any of Examples 1A to 18A, wherein the output indicating a mathematical power estimation of the electronic device is generated in real-time.

Example 1B is A method for training a hardware power estimator configured to provide a power estimate for an electronic device, the hardware power estimator including a scaling circuit configured to receive an input and to generate a scaled non-linear output of the input comprises the scaling circuit applying an approximation of an activation function to the input and a multiply-add (MADD) circuit arrangement configured to generate an output indicating a mathematical power estimation of the electronic device using the output of the scaling, wherein the training may include: providing input from a version of the electronic device to a prototype of the hardware power estimator, determining an output from the prototype of the hardware power estimator based on the provided input; determining a power measurement of the electronic device corresponding to the mathematical power estimation indicated by the output of the prototype of the hardware power estimator; and applying a learning algorithm to difference between the determined output from the prototype hardware power estimator and the determined power measurement to derive optimized weight values for the MADD circuit arrangement of the prototype of the hardware power estimator.

Example 2B is the subject matter of Example 1B, wherein the prototype of the hardware power estimator may be a simulated version of the hardware power estimator.

Example 3B is the subject matter of Example 2B, wherein the electronic device is a simulated electronic device can configured to provide its output as simulated input to the simulated version of the hardware power estimator, wherein determining the power measurement includes performing the power measurement of the electronic device in a simulation.

Example 4B is the subject matter of Example 1B, wherein the prototype of the hardware power estimator may be a physical version of the hardware power estimator.

Example 5B is the subject matter of Example 4B, wherein the electronic device is a physical electronic device may be configured to provide its output as input to the physical version of the hardware power estimator, wherein determining the power measurement includes performing power measurements of the physical version of the electronic device.

It should be noted that one or more of the features of any of the examples above may be suitably or appropriately combined with any one of the other examples or with embodiments disclosed herein.

The foregoing description has been given by way of example only and it will be appreciated by those skilled in the art that modifications may be made without departing from the broader spirit or scope of the invention as set forth in the claims. The specification and drawings are therefore to be regarded in an illustrative sense rather than a restrictive sense.

The scope of the disclosure is thus indicated by the appended claims and all changes which come within the meaning and range of equivalency of the claims are therefore intended to be embraced.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. A hardware power estimator configured to provide a power estimate for an electronic device, the hardware power estimator comprising:
a scaling circuit configured to receive an input and to generate a scaled non-linear output of the input by applying an approximation of an activation function to the input; and
a multiply-add (MADD) circuit arrangement configured to generate an output indicating a mathematical power estimation of the electronic device using the output of the scaling circuit,
wherein the input to the scaling circuit comprises data values representing state information or activity information of one or more components of the electronic device.

2. The hardware power estimator of claim 1,
wherein the scaling circuit comprises a plurality of hardware components configured to perform the approximation of the activation function on the input.

3. The hardware power estimator of claim 2,
wherein the scaling circuit is configured to apply the approximation of the activation function in a piecewise manner to generate, in parallel, a plurality of piecewise outputs, and
wherein the scaling circuit is further configured to multiplex the generated plurality of piecewise outputs to generate the output of the scaling circuit.

4. The hardware power estimator of claim 3,
wherein to generate at least one piecewise output, the scaling circuit is configured to perform a multiply-add operation on the input.

5. The hardware power estimator of claim 3,
wherein to generate at least one piecewise output, the scaling circuit is configured to apply one or more shift operations on the input.

6. The hardware power estimator of claim 3,
wherein to generate at least one piecewise output, the scaling circuit is configured to apply at least one or more shift operations and at least one multiply-add operation to the input.

7. The hardware power estimator of claim 3,
wherein to generate at least one piecewise output, the scaling circuit is configured to apply a comparison operation with predefined thresholds to the input.

8. The hardware power estimator of claim 1, wherein the activation function is a hyperbolic tangent function.

9. The hardware power estimator of claim 1, wherein the activation function is a rectified linear unit function.

10. The hardware power estimator of claim 1,
wherein the MADD circuit arrangement comprises a plurality of MADD circuits arranged in stages so that the output of one stage is input to a subsequent stage.

11. The hardware power estimator of claim 10,
wherein each stage comprises a MADD circuit configured to calculate an accumulated sum of product values from between a first input and a second input to the stage,
wherein the first input is coupled to an output from a previous stage or an output from the scaling circuit, and
wherein the second input is coupled to a memory, and wherein the memory stores predefined weight values.

12. The hardware power estimator of claim 11,
wherein the predefined weight values correspond to one or more electrical parameters and/or states of the electronic device,
wherein the predefined weight values correspond to one or more electrical parameters and/or states of a component of the electronic device, and/or
wherein the predefined weight values correspond to one or more parameters and/or states of a hardware accelerator of the electronic device.

13. The hardware power estimator of claim 11,
wherein the MADD circuit arrangement comprises three stages or less and so as to produce an output from an input in 3 clock cycles or less.

14. A method of hardware power estimation for electronic device, the method comprising:
obtaining an input comprising data values representing state information or activity information of one or more components or Intellectual Property (IP) blocks of the electronic device;
generating, using a scaling circuit, a scaled non-linear output by applying an approximation of an activation function to the input; and
generating, using a multiply-add (MADD) circuit arrangement, an output indicating a mathematical power estimation of the electronic device using the generated scaled non-linear output.

15. The method of claim 14,
wherein the scaling circuit comprises a plurality of hardware components configured to perform the approximation of the activation function on the input, wherein applying the activation function to the input comprises:
generating, in parallel, a plurality of piecewise outputs by applying the activation function to the input in a piecewise manner to, and
summing together the generated plurality of piecewise outputs to generate the scaled non-linear output.

16. The method of claim 15,
wherein the generating of the plurality of piecewise outputs comprises the scaling circuit performing a multiply-add operation on the input,
wherein the generating of the plurality of piecewise output comprises the scaling circuit applying one or more shift operations on the input, and
wherein the generating of the plurality of piecewise output comprises the scaling circuit applying at least one or more shift operations and at least one multiply-add operation to the input.

17. A method for training a hardware power estimator configured to provide a power estimate for an electronic device, the hardware power estimator comprising a scaling circuit configured to receive an input and to generate a scaled non-linear output of the input comprises the scaling circuit applying an approximation of an activation function to the input and a multiply-add (MADD) circuit arrangement configured to generate an output indicating a mathematical power estimation of the electronic device using the output of the scaling circuit,
wherein the training comprises:
providing an input from a version of the electronic device to the hardware power estimator,
determining an output from the hardware power estimator based on the input;
determining a power measurement of the electronic device corresponding to the mathematical power estimation indicated by the output of the hardware power estimator; and
applying a learning algorithm to calculate a difference between the determined output from hardware power estimator and the determined power measurement to derive optimized weight values for the MADD circuit arrangement of the hardware power estimator.

18. The method of claim 17,
wherein the training of the hardware power estimator uses a simulated version of the hardware power estimator,
wherein the electronic device is a simulated electronic device configured to provide its output as simulated input to the simulated version of the hardware power estimator, and
wherein determining the power measurement comprises performing the power measurement of the electronic device in a simulation.

19. A device comprising:
a first bit shifting circuit having an input and an output;
a second bit shifting circuit having an input and an output, the input of the second bit shifting circuit coupled to the output of the first bit shifting circuit;
a multi-add (MADD) circuit having a first input, a second input, and an output, the first input of the MADD circuit is coupled to the input of the first bit shifting circuit, and wherein the second input of the MADD circuit is coupled to the output of the second bit shifted circuit;
a multiplexor having a first input, a second input, a third input, and a select input, wherein the first input of the multiplexor is coupled to the output of the MADD circuit, the second input of the multiplexor coupled to the output of the second bit shifting circuit, and the third input of the multiplexor is coupled to the output of the first bit shifting circuit; and
a comparator having an input and an output, the input of the comparator is coupled to the input of the first bit shifting circuit, the output of the comparator is coupled to the select input of the multiplexor.

20. The device of claim 19, wherein the comparator stores preset values that enable approximation of a non-linear activation function.
